(19) United States
(12) Patent Application Publication
(10) Pub. No.: US 2011/0220874 A1
(43) Pub. Date: Sep. 15, 2011

(54) Inorganic Bulk Multijunction Materials and Processes for Preparing the Same

(76) Inventors: Tobias Hanrath, Ithaca, NY (US); James R. Engstrom, Ithaca, NY (US)

(21) Appl. No.: 13/057,535

(22) PCT Filed: Aug. 10, 2009
(86) PCT No.: PCT/US2009/053298

§ 371 Date: May 24, 2011

Related U.S. Application Data
(60) Provisional application No. 61/087,455, filed on Aug. 8, 2008.

(51) Int. Cl. H01L 29/15; H01L 21/20

(52) U.S. Cl. 257/22; 438/486; 257/E21.09; 257/E29.075

(57) ABSTRACT

A nanostructured composite material comprising semiconductor nanocrystals in a crystalline semiconductor matrix. Suitable nanocrystals include silicon, germanium, and silicon-germanium alloys, and lead salts such as PbS, PbSe, and PbTe. Suitable crystalline semiconductor matrix materials include Si and silicon-germanium alloys. A process for making the nanostructured composite materials. Devices comprising nanostructured composite materials.

### CROSS-REFERENCE TO RELATED APPLICATIONS

This application claims priority to U.S. Provisional Patent Application No. 61/087,455, filed Aug. 8, 2008, which is incorporated herein in its entirety.

### STATEMENT REGARDING FEDERALLY SPONSORED RESEARCH

This invention was made with government support under grant number CBET 0828703 awarded by the National Science Foundation. The government has certain rights in the invention.

### FIELD OF THE INVENTION

This invention relates generally to the field of photovoltaic and thermoelectric devices and more particularly to composite materials for use in production of solar cells.

### BACKGROUND OF THE INVENTION

Over 95% of currently available solar cells are based on silicon. In spite of the vast elemental abundance of silicon and mature and efficient silicon photovoltaic technology, these solar cells are not economically competitive with other energy sources. The recent steep increase in production volume has steadily dropped the production cost of silicon-based solar cells, however, extrapolation of this trend shows that conventional photovoltaic technology is unable to make a significant contribution to the rapidly rising global energy demands.

The silicon wafer from which the solar cells are made accounts for approximately 65% of the solar cell cost. Intensive efforts have been aimed at reducing the material cost by either producing thinner cells or by using cheaper, lower-quality (polycrystalline) silicon. In both cases, the net benefit of lowering the material cost is offset by a pronounced reduction in solar cell efficiency. The reduced efficiency in polycrystalline silicon solar cells is due to the low mobility of photogenerated carriers, which limits the number of carriers that reach the external electrodes. Thus, there continues to be an on-going and unmet need for scalable technology to efficiently convert solar and/or thermal energy to electrical energy.

### BRIEF SUMMARY OF THE INVENTION

The present invention provides a new material architecture. In one aspect, the present invention provides a nanostructured composite material comprising semiconductor nanocrystals (NCs) (e.g., Si, Ge, Si—Ge alloys, PbS, PbSe, PbTe, etc.) in a semiconductor matrix. The composite material is prepared such that the structure and properties of the nanocrystals are preserved, i.e., the nanocrystals are discernable and have an ordered arrangement in the composite.

In another aspect, the present invention provides a method for preparing the nanostructured composite materials. In one embodiment, the method of making a nanocrystal composite material comprises the steps of: (a) on a substrate, forming a layer of pre-composite material (which is comprised of an amorphous semiconductor matrix into which semiconductor nanocrystals are incorporated (examples of incorporated include, but are not limited to, encapsulated and/or embedded); and (b) subjecting the materials from (a) to crystallizing conditions such that the amorphous semiconductor matrix material is crystallized, and the semiconductor nanocrystals exhibit properties characteristic crystalline structure, to form a nanocrystal composite material.

The nanostructured composite materials can be used to realize inorganic bulk heterojunction (e.g. Si/Ge or Si/PbSe) or bulk homojunction photovoltaic and/or thermoelectric cells. Devices using the photovoltaic/thermoelectric cells of the present invention can be used for application such as, but not limited to, renewable energy harvesting (i.e., solar) and thermal management (i.e., waste heat recovery).

### DESCRIPTION OF THE FIGURES

FIG. 1. SEM images of PbSe NC monolayer before (A) and after (B) sputter deposition of a-Si top layer. (C) Photograph of PbSe/a-Si composite on a Si wafer after exposure to a matrix of laser annealing conditions. (D&E) corresponding small-angle and wide-angle x-ray diffraction of PbSe/polysilicon composites. PbSe (Si) characteristic x-ray diffraction reflections are shown at the bottom (top).

FIG. 2. GISAXS pattern of PbSe NC films. (A) initial disordered NC film and (B) high spatial coherence in the same film following solvent vapor annealing.

FIG. 3. Graphical depiction of processing steps for fabrication of inorganic bulk multijunction solar cell.

FIG. 4. Graphical depiction of possible bulk multijunction (BMJ) solar cell configurations. (A) ordered nanocrystal BMJ, (B) disordered nanocrystal BMJ, (C) ordered nanowire BMJ, and (D) disordered nanowire BMJ.

FIG. 5. Graphical depiction of operating principle of the BMJ. (A) Photon absorption, exciton dissociation and charge transport. TEM image of PbSe nanocrystals. (B) Donor-Acceptor energy level alignment, (C) Multiexciton generation (MEG).

FIG. 6. Schematic illustration of multi-mode photovoltaic/thermoelectric device structure. Incident photons are converted to electron/hole pairs while phonons are strongly scattered at nanostructured interfaces.

### DETAILED DESCRIPTION OF THE INVENTION

The present invention provides a new material architecture. The present invention also provides a method for preparing the nanostructured composite materials.

In one aspect, the present invention provides a nanostructured composite material comprising semiconductor nanocrystals (NCs) (e.g., Si, Ge, Si—Ge alloys, PbS, PbSe, PbTe, etc.) in a semiconductor matrix. The composite material is prepared such that the structure and properties of the nanocrystals are preserved, i.e., the nanocrystals are discernable and have an ordered arrangement in the composite.

In one embodiment, the nanocrystal composite material comprises a plurality of semiconductor nanocrystals incorporated into a crystalline semiconductor matrix, and the majority of the nanocrystals have an ordered arrangement within the composite. In another embodiment, the crystalline structure and optical properties of the nanocrystals in the composite material are the same or similar as those of semiconductor nanocrystals in the absence of the matrix.

Semiconductor nanocrystals are components of the nanostructured composite materials where conversion of light and/or thermal energy to charge carrier(s) is achieved. The NCs preferably have electronic properties such as, but not limited to: (1) high absorption cross section for efficient light capture; strong quantum confinement effects to provide the necessary degrees of freedom to size-tune optical properties for optimal absorption of the solar emission spectrum; (2) strong electronic coupling between neighboring NCs to permit efficient charge transport while at the same time passivating the surface to prevent interface charge recombination; and (3) for thermoelectric conversion, dense boundaries to enhance phonon scattering and minimize thermal conduction for high ZT thermoelectric properties. The NCs should be synthesized with methods offering size, shape and composition control.

A variety of NCs compositions possess the required properties for use in the present invention. Examples of NC compositions useful in the present invention include, but are not limited to, III-V and II-VI compound semiconductors, e.g. Si, Ge, SiGe alloys. Other examples include, but are not limited to, lead salts such as PbS, PbSe, PbTe. For example, commercially available NCs or independently synthesized NCs can be used in the present invention.

NCs with any shape can be used in the present invention. For example, spherical NCs are suitable. Other shapes can also be used, e.g. rod, wires, tetrapods, cubes, platelets. One dimensional structures (wires) can be used and offer the advantage that they offer connection for charge transport in one direction.

NCs in the size range from 2 nm to 30 nm (including all integers between 2 nm and 30 nm) are suitable for the present invention. The particles can be spherical or quasi-spherical (e.g. truncated octahedral). For spherical or quasi-spherical particles the size of the particles is the longest dimension. For other particle morphologies, the size of the particles is such that at least one dimension is in the range of 2 nm to 30 nm. The NCs should have a relative size distribution (std. dev./mean size) such that ordered structures can be formed. For example, a standard deviation of <10% of the mean size can lead to ordered structures. For non-spherical structures (e.g. cubes) decreasing relative size distribution is preferable. For example, PbS and PbSe NCs of from 2 nm to 30 nm can be used.

The band gap of the semiconductor nanoparticles can be such that the nanoparticles can absorb incident energy which can be converted to electrical energy. For example, due to the large Bohr diameter of the exciton in lead-salts the energy gaps of these salts can be size-tuned from 0.4 to nearly 2 eV enabling solar energy conversion to be extended into the near infra-red. Photons with energy greater than the bandgap can also be absorbed and converted. For example, in the case of lead-salt NCs particle size can be modified to result in conversion of photons with energy greater than the band gap.

Thermal energy is converted to electrical energy using the materials of the present invention by onverting a thermal gradient (across device structure comprising the nanostructured composite material of the present invention) into a potential gradient. Without intending to be bound by any particular theory, it is considered that in a multimode device (comprising photovoltaic and thermoelectric energy conversion) concomitant photoexcitation further enhances thermoelectric energy conversion efficiency.

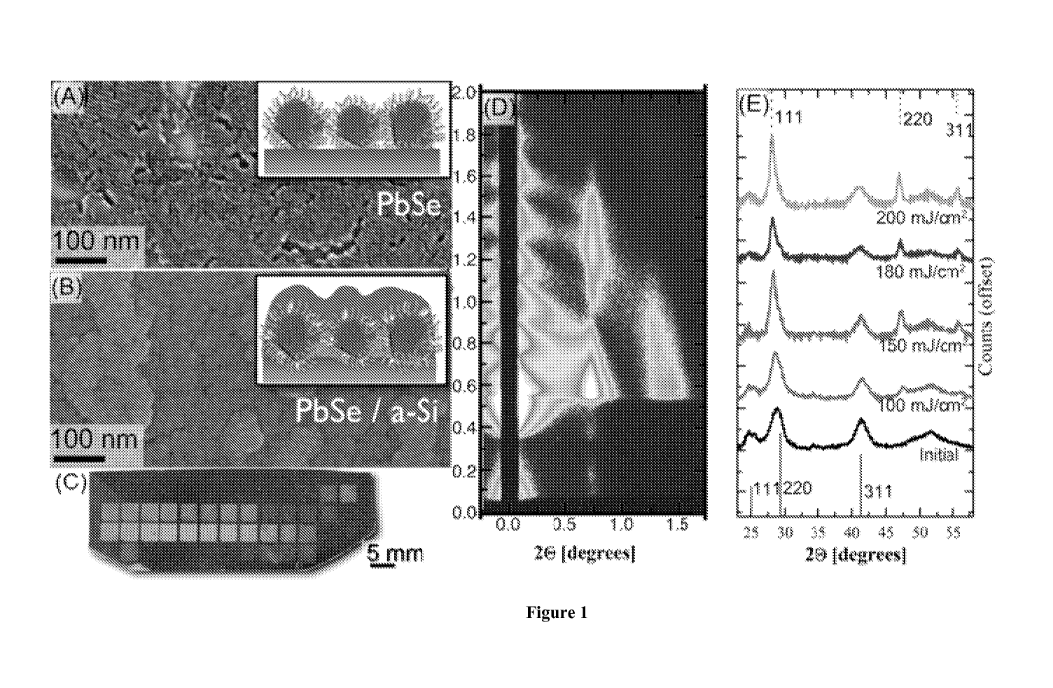

In one example, PbSe nanocrystals are used. An example of these nanocrystals is shown in FIG. 1. These nanocrystals are in the size range of from 2-10 nm. Due to the large PbSe Bohr exciton diameter (46 nm), this size range results in a nanocrystal energy gap of from 1.4 to 0.4 eV. This energy gap allows solar energy conversion in the near infrared wavelength regime.

Without intending to be bound by any particular theory, a large Bohr diameter also plays a critical role in overcoming the ostensible contradiction between quantum confinement, to yield the desired size-tuned properties, and ‘un-confinement’ to enable efficient charge transport from the point of photogeneration to the external electrodes. When combined with chemical treatments to modulate the interparticle spacing, the strong wavefunction overlap translates into tunable electronic coupling of proximate NCs and enhancement of the NC film conductivity.

In another embodiment of this invention, the integration of SiGe alloy nanocrystals in a polycrystalline Si matrix, can be used to fabricate intermediate band photovoltaic/thermoelectric cells.

The semiconductor matrix material conducts the carriers generated by the semiconductor nanocrystals and provides structural support during the laser annealing process. The matrix is selected to provide high carrier mobility and concentration. For example, the matrix material can be tuned to be either a p- and/or n-type conductor. Generally, the semiconductor matrix material in the nanostructured composite is present in a crystallized form. Any semiconducting materials that can be laser annealed to yield crystalline matrix material can be used. Examples of a suitable crystalline matrix material include, but are not limited to, crystalline silicon and Si₁₋ₓGeₓ.

The semiconductor matrix material can be deposited on a substrate on which nanocrystals have already been deposited. Alternatively, a precursor material to the semiconductor matrix material can be combined with the active nanocrystals and the resulting material coated on a substrate and the precursor material converted to semiconductor matrix material.

Any substrate with surface such that it can be coated with a thin film of the semiconductor nanocrystals and/or semiconductor matrix material (or semiconductor precursor material) (e.g. appropriate surface roughness and surface energy) can be used in the present invention. In one example, the substrate is conducting or semiconducting. The substrate should be sufficiently stable to withstand thermal annealing conditions or laser annealing conditions. For example, flexible and polymer based substrates can be used. As another example, a silicon wafer can be used as a substrate.

The nanoparticles have an ordered arrangement within the composite. Ordered is defined as long range spatial coherence (i.e., translational and/or orientational order). For example, NCs undergo ‘self-assembly’ if the NC diameter distribution is sufficiently narrow.

An additional driving force behind the formation of ordered structures is the NC dipoles. For example, dipoles can arise from an uneven distribution of Pb and Se terminated {111} facets of individual NCs. Without being bound by any particular theory, it is considered that the dipole moment of the nanoparticles will affect the order of the composite structure. For example, PbSe nanocrystals exhibit strong dipole moments, and it is considered that such dipole moment characteristics can lead (via dipole-dipole coupling, for example) to formation of ordered highly anisotropic nanostructures (e.g., wires or disordered networked structures), via oriented attachment and assembly of NC films with non-close packed, simple-hexagonal symmetry.

Without intending to be bound by any particular theory, it is considered that of three-dimensional structures with more complex geometries providing contact points (for charge transport) at adjoining nanocrystals are formed from individual PbSe NC building blocks using laser annealing.

The nanoparticles in the composite have a discernable crystalline structure. The structure and properties of the nanoparticles in the composite is substantially similar to that of the nanoparticles used to produce the composite. The structure and spatial coherence of the nanocrystals in the composite material can be determined using wide-angle and small-angle x-ray scattering/diffraction. For example, the structural similarity is demonstrated by small-angle (or wide-angle) x-ray scattering/diffraction data showing that the properties (e.g. crystal structure and size) of the nanocrystals in the crystalline semiconductor matrix of the composite material are characteristic of the nanocrystals used to produce the composite material. In one example, a lack of change in the width and position of the wide angle x-ray scattering are unchanged demonstrating that the nanocrystals are not altered. As another example, the nanoparticles are substantially similar in that the size-dependent excitonic absorbance features (in the optical absorbance spectrum) are indicative of a characteristic of the nanocrystals used to produce the composite material. In one example, a decrease in particle size would lead to a blue shift in excitonic absorption peak. In another example, a broadening of the absorption peak corresponds to a broadening of the NC size distribution.

In the composite material the NC-matrix boundary is a direct inorganic-inorganic interface. This is more desirable for minimal charge recombination. For example, the nanocrystals can be prepared as a colloidal suspension where the NC surfaces are passivated with organic ligands. Preparation of the composite material leads to a direct inorganic-inorganic interface and the size dependent optical properties are unchanged.

The crystallinity of the semiconductor matrix material can be assessed by the grain structure of the material. For example, for a silicon matrix material, WAXS shows that nanocrystals stay crystalline with a grain size corresponding approximately to the NC diameter (6 nm). The grain size of the Si matrix can be tuned depending on the laser conditions. For example, the silicon matrix grain size ranges from 8 to 20 nm.

The ratio of NC to matrix can be as high as 0.74 (volume fraction). This volume fraction is for close packed structures of spherical particles. For other symmetries the volume fraction will be slightly less (e.g. 0.68 for body-centered symmetry). The volume fraction can be as low as 0.2. For spherical particles, the lower level is approximately the percolation threshold for spherical particles. It is considered that the volume fraction for spheres which interact via dipoles can be as low as 0.2. In one embodiment, the NC to matrix ratio (volume fraction) is from 0.2 to 0.74, including all decimal parts to the tenth and hundredth. In various other embodiments, the ratio of NC to matrix (volume fraction) is 0.3, 0.4, 0.5, 0.6, and 0.7. It is desirable to have a volume fraction such that the nanocrystals are in electrical contact (i.e. connected) with at least one neighboring nanocrystal. Without intending to be bound by any particular theory, it is considered that having the nanocrystals connected results in higher energy conversion efficiency of the composite material.

In one embodiment, a majority of the nanocrystals in the composite are in such proximity that they are in electrical contact. For example, physical contact between nanocrystals can result in electrical contact. In another embodiment, a plurality of nanocrystals in the composite is such proximity that the nanocrystals are in electrical contact. In various other embodiments, 60, 70, 80, 90, 95, and 99 percent of the nanocrystals are in such proximity that they are in electrical contact.

The thickness of the composite layer can be from 20 to 400 nm (including all integers between 20 and 400 nm). In various embodiments, the thickness of the composite layer is 20, 30, 40, 50, 60, 70, 80, 90, 100, 125, 150, 175, 200, 225, 250, 275, 300, 350, and 400. The thickness can be controlled by varying the synthesis and deposition conditions.

It is expected that material architecture of the present invention will address the low mobility problem in solar cells built from low-cost polycrystalline semiconductors

In another aspect, the present invention provides a method for preparing the nanostructured composite materials. In one embodiment, the method of making a nanocrystal composite material comprises the steps of: (a) on a substrate, forming a layer of pre-composite material (which is comprised of an amorphous semiconductor matrix into which semiconductor nanocrystals are incorporated (examples of incorporated include, but are not limited to, encapsulated and/or embedded)); and (b) subjecting the materials from (a) to crystallizing conditions such that the amorphous semiconductor matrix material is crystallized, and the semiconductor nanocrystals exhibit properties characteristic crystalline structure, to form a nanocrystal composite material.

In one embodiment, the forming of a layer of pre-composite material is carried out by first depositing nanocrystals on the substrate and then forming the amorphous semiconductor matrix. The layer of pre-composite material can be formed by first mixing semiconductor nanocrystals and precursors of an amorphous semiconductor matrix material and then depositing the mixture on the substrate. The formation of the amorphous semiconductor matrix can also be carried out by (1) deposition of precursor material followed by conversion of the precursor material to the amorphous semiconductor material, or (2) deposition of the amorphous semiconductor material.

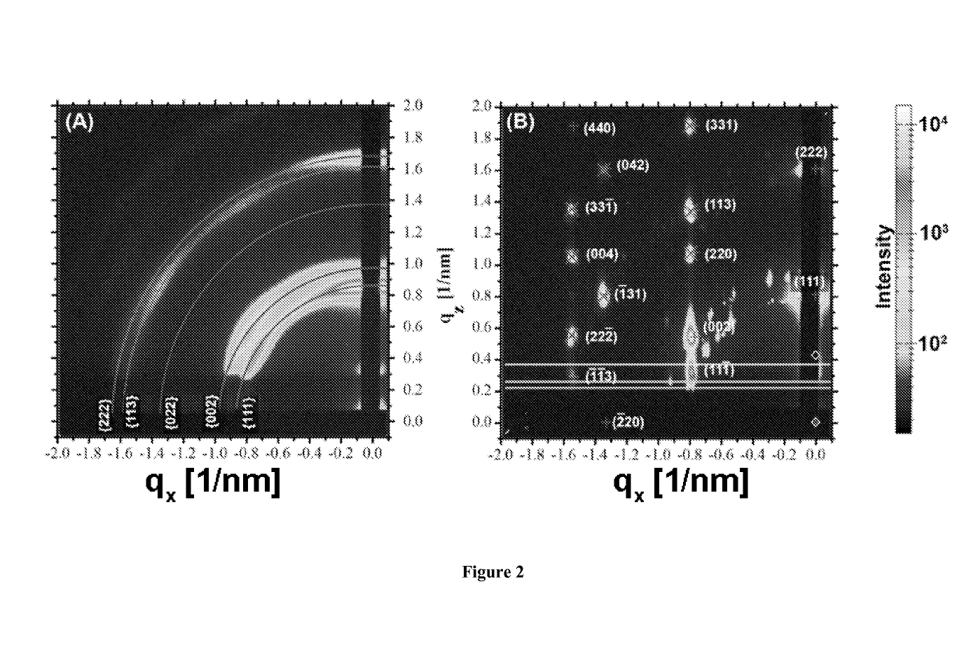

For example, the nanostructured composites of the present invention can be fabricated as is illustrated in FIG. 2. Semiconductor nanocrystals are deposited onto the substrate (such as in the form of thin film via conventional methods such as, but not limited to, spin coating, drop casting, ink-jet printing or doctor blading from solution). The semiconductor nanocrystals can be in the form of a colloidal suspension. The nanocrystals can then optionally be subjected to physical or chemical treatments to ensure a high mobility of photogenerated carriers.

An example of a chemical treatment involves replacing the original oleic acid ligand with a shorter molecule (for example, short-chain thiols or amines). Examples of physical treatments include, but are not limited to, UV/ozone and plasma treatment. Where the nanocrystals comprise oleic acid, the physical treatments can result in removal of the oleic acid (e.g., by degredation of the oleic acid molecules). Other examples of such treatments include the solution phase ligand exchange using thiols (e.g., butanethiol), dithiols (e.g., 1,2-ethanedithiol), hydrazine, amines (e.g., butyl amine or pyridine), and alcohols (e.g., ethanol). Without intending to be bound by any particular theory, it is considered that alcohols only displace the oleic acid ligand and do not actually bind to the NC surface as is the case with the other examples.

In one embodiment, the invention may be readily interfaced with surface passivation techniques (such as chemical vapor deposition (CVD) or atomic layer deposition (ALD)) to passivate the nanocrystal surface. It is considered that the surface passivation techniques may result in high photocurrents and efficient interface charge transport.

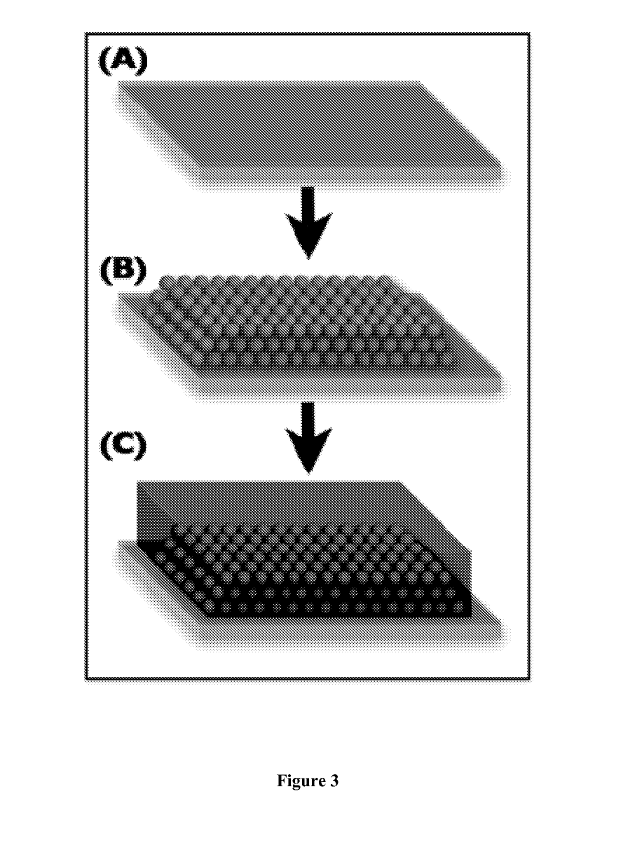

In one embodiment, the deposited nanocrystals are subjected to solvent vapor annealing. For example, the deposited nanocrystals are subject to octane vapor. Without intending to be bound by any particular theory it is considered that solvent vapor annealing can significantly enhance long range translational and orientational ordering of the deposited nanocrystals. This is shown in FIG. 3.

In a subsequent step, the semiconductor matrix material can be formed (e.g. as a thin film) on a substrate. The matrix material can be deposited on a substrate on which nanocrystals have already been deposited or a precursor deposited on the film can be converted to the matrix material. Alternatively, a precursor to the semiconductor matrix material can be combined with the nanocrystals and the resulting material coated on a substrate and the precursor material converted to semiconductor matrix material.

In one embodiment, fluid precursor of the semiconductor matrix material is introduced to fill the gaps of the first layer and thus completely encapsulate or embed the nanocrystals. The encapsulation or embedding of the nanocrystal array can be accomplished by several means. For example, the precursor can be deposited from vapor, liquid, or supercritical fluid phase. An important advantage of the use of supercritical fluids is the absence of surface tension effects permitting the dissolved precursor to permeate all void spaces in the nanocrystal layer underneath.

In another embodiment, the photon harvesting elements (e.g. semiconductor nanocrystals) and conducting matrix (e.g. liquid semiconductor precursor) may be combined and deposited as one solution by the methods listed above. In this embodiment, the total number of processing steps is reduced and may result in better encapsulation of the nanocrystals.

In another processing step, the deposited precursor material is subjected to physical and/or chemical treatments to convert the liquid semiconductor precursor to a solid conducting matrix. Generally, the semiconductor matrix material is formed as an amorphous material (i.e., no long range order is observed in the material). For example, in the case of a cyclopentasilane precursor material, these steps include photoinitiated polymerization, followed by thermal annealing and laser induced crystallization. These steps result in the formation of a polycrystalline semiconductor matrix encapsulating the nanocrystal. Other semiconductor matrix materials (including, for example, Ge, SiₓGe₁₋ₓ, etc.) can be deposited, using the above methodology through rational selection of precursor solutions.

For example, a silicon semiconductor matrix can be deposited using a liquid semiconductor precursor such as, but not limited to, organosilanes (e.g. cyclopentasilane). For example, polycrystalline Si films with grain sizes and mobilities on the order 200 nm and 100 cm²-V-s⁻¹, respectively, can be prepared by deposition of a cyclopentasilane, formation of polysilanes via photoinitiated ring opening polymerization of cyclopentasilane (c-Si₅H₁₀), followed by thermal annealing (300-400° C.) desorbing most of the hydrogen and forming amorphous silicon. In a final step an excimer laser is used to crystallize the silicon, forming essentially a pure polycrystalline silicon thin film.

In one embodiment, instead of depositing a precursor material, the semi-conducting matrix in an amorphous form can be deposited, for example, using vacuum-based techniques such as, but not limited to, thermal evaporation, atomic layer deposition, chemical vapor deposition, or sputtering.

Complete encapsulation of photon harvesting material, such as semiconductor nanocrystals, may reduce end of life toxicity concerns related to some nanocrystals. (For example, PbSe embedded in and inorganic matrix are environmentally benign, whereas the same nanocrystals embed it into a polymeric matrix are susceptible towards leaching at the end of their useful life.)

After formation of the amorphous semiconductor matrix, the matrix material is crystallized. The crystallization is carried out such that there is no or minimal degradation of the nanocrystal morphology. The structure of the nanocrystals are retained as evidenced by the size and crystal structure of the nanocrystals as determined by x-ray scattering/diffraction data and/or the properties of the nanocrystals are retained as evidenced by the size-dependent excitonic absorbance features in the optical absorbance spectrum.

For example, the crystallization can be carried out by laser surface irradiation. For example, pulsed laser surface irradiation with a XeCl excimer laser (λ=308 nm, FWHM=35 ns) at a fluence sufficient to induce surface melting (for example, 200-1000 mJ/cm²). Without intending to be bound by any particular theory, it is considered the pulsed laser surface irradiation causes melting at depths up to 500 nm with the duration of the laser pulse (20 ns), followed by rapid solidification as heat is conducted in the substrate (typically 50-200 ns). In this time regime solid-phase kinetics are suppressed due to the short times, liquid phase mixing of miscible materials is nearly complete, and immiscible liquid phase kinetics are severely restricted.

The crystallization can also be carried out using longer timescales (10's of microseconds to several milliseconds, for example) at temperatures near the melting temperature of the matrix, but maintaining the matrix material in the solid phase. For example, a continuous wave laser (e.g., CO₂ (λ=10.6 microns)) or fiber coupled diode laser diode (λ=980 nm) at a power level of 100-250 W). Without intending to be bound by any particular theory, it is considered that grain refinement of the nanocrystals into larger particles will not occur.

In another aspect, the present invention also provides a product made using the process(es) disclosed herein.

In another aspect, the present invention provides a photovoltaic cell device which is comprised of a nanostructured composite material. In one embodiment, the photovoltaic cell device comprising the nanostructured composite material is disposed between two conducting layers.

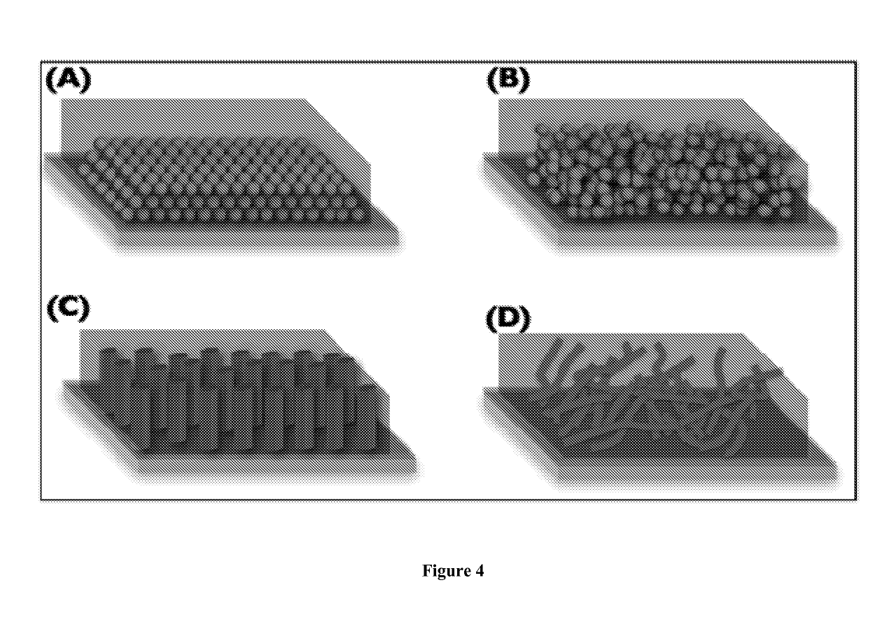

In yet another aspect, the present invention provides a multimode photovoltaic/thermoelectric cell device comprising the nanostructured composite material. In one embodiment, the multimode devise comprises adjacent p-type (hole conducting) and n-type (electron conducting) domains (each comprising a nanostructured composite material) disposed between two conducting layers. A schematic illustration of a multimode photovoltaic/thermoelectric device is shown in FIG. 4.

Without intending to be bound by any particular theory, it is considered that photoexcitation can enhance thermoelectric energy conversion. This enhancement can result from more efficient phonon scattering at the nanostructured interface, electron transport (including high carrier mobility and concentration) and quantum confinement of the nanostructured composite material of the present invention.

For example, in light of the high absorption cross section and low volume average carrier density (0.002 per 4.3 nm diameter NC corresponding to ˜1015 cm⁻³), it is considered that PbSe NC composite materials can exhibit photoexcitation-enhanced thermoelectric energy conversion.

To a first approximation, we can predict the effect of photoexcitation on thermopower in a classical semiconductor, by: Se=±(kBq−1)(2+ln(Ni/ni)), where the negative sign is for electrons and the positive for holes; Se is the Seebeck coefficient, Ni is the effective density of states in the band; and ni is the density of free carriers. If both electrons and holes are considered, the effect of photoexcitation on thermopower cancels out. If, on the other hand, transport is dominated by either electrons or holes, photoexcitation would raise ni and decrease the thermopower. Experimentally, however, photoexcitation was observed to increase the thermopower in p-type silicon. The discrepancy between model and experiment stems from the oversimplified assumption of homogeneous charge transport and a Boltzmann distribution. In nanostructured semiconductors, this discrepancy is expected to be much more pronounced and numerous previous studies have shown that charge transport in free standing and embedded nanostructures is highly sensitive to surface effects. These findings strongly support the expectation of a similar anomalous photo-thermoelectric effect in the PbSe NC based composite materials of the present invention.

In another embodiment of this invention, sequential application of the processing steps outlined below combined with suitable recombination layers can be used to prepare multi junction photovoltaic/thermoelectric cells comprised of nanocrystal-based active layers with cascaded energy gaps.

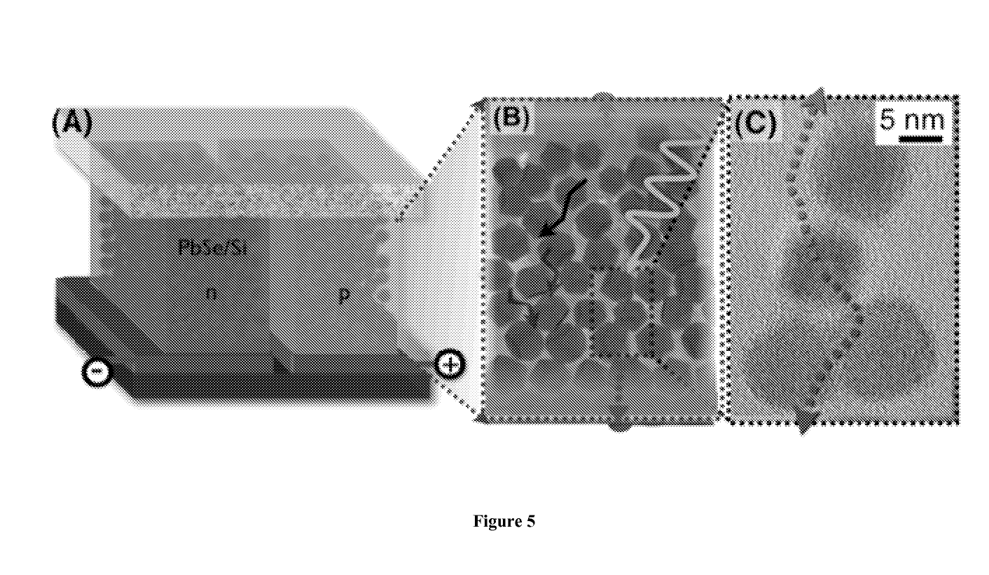

Depending on the nature of the nano- or microcrystalline semiconductor used for the first layer, this invention enables the fabrication a diverse set of inorganic heterojunction and homojunction solar cells. FIG. 5 illustrates four possible options.

The nanostructured composite materials can be used to realize all-inorganic bulk heterojunction (e.g. Si/Ge or Si/PbSe) or bulk homojunction photovoltaic and/or thermoelectric cells. Devices using the photovoltaic/thermoelectric cells of the present invention can be used for application such as, but not limited to, renewable energy harvesting (i.e., solar) and thermal management (i.e., waste heat recovery).

To realize the true potential of BMJ solar cells, three key criteria have to be met: (1) the energy levels of the composite materials have to align complimentarily to facilitate dissociation of photogenerated excitons into free charges at the interface, (2) the kinetics of exciton dissociation and charge transport have to be faster than their recombination, and (3) the morphology of the hybrid material has to provide high interface area for exciton dissociation and simultaneously a continuous transport pathway for each charge to their respective external electrode. All three criteria are critically sensitive to the chemical and physical interface properties.

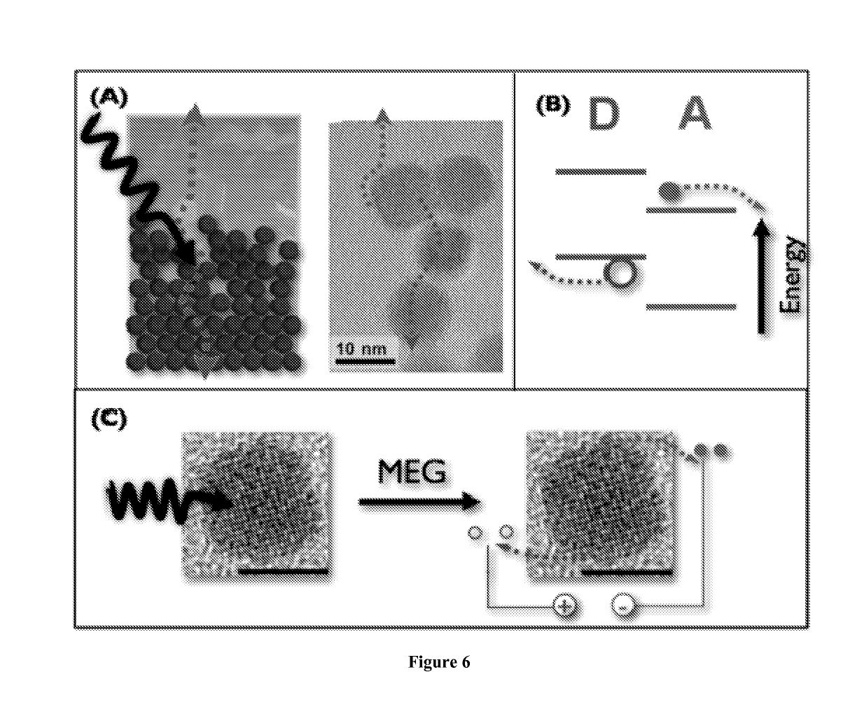

The device architecture of the present invention successfully addresses these three criteria. FIG. 6 descries the operating principle of the BMJ solar cell. FIG. 6A illustrates how a photon is absorbed by the nanocrystal and split into an electron-hole pair. The charges are separated at the nanocrystal/matrix interface and transported to their respective electrodes. The energy level alignment of the electron donor (D) and electron acceptor (A) illustrate the energetic requirements for exciton dissociation at the interface (FIG. 6B). Multiexciton generation (MEG)—the unique ability of semiconductor nanocrystals to convert high energy photons into multiple electron-hole pairs, is illustrated in FIG. 6C.

The present invention has a number of unique features including:
1. A solid-state inorganic semiconductors photovoltaic/thermoelectric cell, fabricated from solution enabling low-cost, high throughput processing techniques.
2. A low-cost, thin film photovoltaic/thermoelectric cell in which unstable organic components in the active layers are avoided. This configuration provides superior photostability and allows the fabrication of solar cells with lifetimes similar to those of conventional silicon solar cells (˜20 years). In contrast, the lifetime of polymer-based solar cells is severely limited (<˜2 years) by the inherently photosensitive polymer.
3. The invention provides a device platform that completely encapsulates semiconductor nanocrystals in a semiconductor matrix with complementarily electronic properties. The electronic properties of this interface are far superior to those of organic/inorganic interface in polymer based hybrid solar cells.
   a. The enhanced interface properties enable a means to fully exploit the unique photon harvesting characteristics of the encapsulated nanocrystals. Two particularly important options benefiting from efficient and fast interface transfer of photogenerated charges are:
      i. Multiexciton solar cells. Multiexciton generation converts a single incident solar photon into multiple electron hole pairs, and opens the door toward solar cells with efficiencies surpassing the notorious Shockley-Queisser limit (˜32%) for single band gap semiconductors. This process has been observed in a range of semiconductor nanomaterials including PbSe, PbTe, CdSe, InAs, and most recently Si.
      ii. Hot carrier solar cells. Extracting photo generated charges before they relax to their respective band edges permits the recovery of their full kinetic energy, which would otherwise be lost as heat.
   b. This invention is adaptable to a broad range of material combinations. The detailed description below illustrates the combinations of a polycrystalline Si matrix with either Si, Ge, PbSe, or PbTe nanocrystals. This can be readily extended to other material systems of low-cost nano- or microcrystalline semiconductors, provided that the energy level alignment of the constituent materials supports favorable charge separation as required for application in solar energy conversion.
4. The invention is based, in various embodiments, on low-temperature solution processing methods which enable the use of low-cost substrates and substantially reduce the base of system cost of the photovoltaic/thermoelectric cell module.
5. The invention is based, in various embodiments, on low-temperature solution processing methods which can be applied to flexible substrates and thus enable low-cost roll-to-roll processing.
6. The ability to effectively interface nanoscale semiconductor materials can be important in applications beyond their integration into photovoltaic/thermoelectric devices. (For example, the processes and materials of the present invention can be used to produce hybrid light emitting diodes, nanocrystal based electronic systems, energy storage, etc.)

The processes and materials of the present invention can be used in fabrication of high-efficiency solar cells from low-cost materials, solution based processing of photovoltaic/thermoelectric cells, and roll-to-roll photovoltaic/thermoelectric cell fabrication on flexible substrates.

The following example is intended to further describe the invention and is not intended to limit the scope of the invention in any way.

### Example 1

### Nanocrystal Synthesis

### Colloidal PbSe NCs Will be Synthesized According to a Slightly Modified Version of the Hot-Injection Method

Thin film processing: The optimal colloidal NCs deposition method depends on a variety of factors. Although spin-casting is the method of choice for most organic thin films, the formation of homogeneous NC films with smooth surfaces and high spatial coherence has favored alternative methods including Langmuir films, drop casting, dip-coating or slow evaporation on tilted substrates. These techniques provide control over a broader range of solvent evaporation rates and are more compatible with additional solution-based processing methods that often accompany NC thin-film processing.

Two complementary approaches are used to fabricate thin films comprised of PbSe NC encapsulated in an amorphous Si matrix. In the first approach, a NC monolayer is deposited from a colloidal suspension followed by sputter deposition of an amorphous silicon (a-Si) or silicon-germanium alloy (a-SiGe) film to encapsulate the nanocrystal layer.

In the second approach, colloidal NC suspensions in cylopentasilane are deposited using the linear-stage convective assembly technique, which is particularly attractive since it combines control over the spatial coherence and the prospect of linear alignment of the nanostructures through viscous drag of the suspension.

Encapsulation and matrix crystallization: Crystallization of the a-Si/a-Ge matrix via conventional thermal annealing would require conditions (e.g., several hours at >400° C.) that are likely to degrade the NC morphology. Instead, we use laser annealing to crystallize the matrix, which offers the degrees of experimental freedom required to rigorously control the kinetic aspects of the matrix and/or nanoparticle melting and crystallization. Computational predictions of the melting and diffusion dynamics can be used to make systematic adjustments in laser pulse duration and intensity to control the extent of diffusion and intermixing during crystallization process.

Two distinct crystallization regimes are accessible. In one regime, pulsed laser surface irradiation with an XeCl excimer laser (λ=308 nm, FWHM=35 ns) at a fluence (200-1000 mJ/cm2) is used to induce surface melting. This melting occurs to depths up to 500 nm within the duration of the laser pulse (20 ns), followed by rapid solidification as heat is conducted into the substrate (typically 50-200 ns). In this regime, solid-phase kinetics are entirely suppressed (insufficient time), liquid phase mixing of miscible materials is nearly complete, and immiscible liquid phase kinetics are severely restricted. For a silicon matrix, the NC will melt before the matrix resulting in immiscible “droplets” of the NC initially in a solid matrix and then dispersed in the molten Si. During solidification, the matrix will crystallize first leaving the liquid NC droplets which subsequently solidify within the rigid matrix. This is expected to form nearly spherical NC particles from the surface tension, and potentially epitaxial relationships between the matrix and NC particles. For a Ge matrix, the matrix will melt before the NC particles, leaving fully faceted particles dispersed in an initial liquid matrix. At fluences sufficient to only melt the matrix, the NC particles will retain much of the shape (and potentially truncated asymmetry) and crystallinity. The matrix would then crystallize around the NC particles, seeding potentially as heteroepitaxy from the NC seeds. At higher fluences, the NC particles will also melt leading to immiscible NC droplets in the Ge liquid matrix. During cooling, the NC particles will supercool and—if kinetically permitted—crystallize first followed by the Ge matrix at lower temperatures. For, a SiGe alloy matrix, as Si and Ge are completely miscible over the full binary composition range, alloys provide access to all conditions between the two limiting cases. For pulsed laser melting, the effective “melting temperature” (T₀ curve) is nearly linear with composition between 1683 K (Si) and 1210 K (Ge). Hence the composition can be tuned to match the (reduced) melting temperature of the NCs.

This liquid phase induced crystallization results in the highest quality semiconductor matrix and will fully envelop the NC seeds. Additionally, the high temperatures and reactive character of the Si or Ge melt will fully remove the organic ligands surrounding the NC leaving pure NC structures. Finally, by controlling the duration of the melt (through substrate temperature and fluence), migration of the NC particles to form interconnected networks can be controlled.

A second regime for annealing of the matrix relies on much longer timescales (10's of microseconds to several milliseconds) near the melting temperatures but remaining within the solid phase. This regime is accessed using a scanned CW laser, either a CO₂ (λ=10.6 um) laser or a fiber coupled diode (λ=980 nm) laser at power levels of 100-250 W. Although similar to furnace annealing, CW laser annealing is sufficiently short that grain refinement of the NCs into larger particles will not occur (certainly for the 10 μs regime). Temperatures can be achieved just short of the matrix melting temperature, with full crystallization of Si and Ge materials occurring in the sub-ms time scale at temperatures above 0.8Tₘ. For the high temperature matrix (Si), full melting of the NC is possible with subsequent solidification into near perfect crystals.

1) A method of making a nanocrystal composite material comprising the steps of:
a) on a substrate, forming a layer of pre-composite material comprising an amorphous semiconductor matrix into which are incorporated semiconductor nanocrystals; and
b) subjecting the materials from a) to crystallizing conditions such that the amorphous semiconductor matrix material is crystallized and the semiconductor nanocrystals exhibit properties characteristic crystalline structure, to form a nanocrystal composite material.

2) The method of claim 1, wherein the forming a layer of pre-composite material step in a) is carried out by first depositing nanocrystals on the substrate and then forming the amorphous semiconductor matrix.

3) The method of claim 1, wherein the forming a layer of pre-composite material step in a) is carried out by first mixing semiconductor nanocrystals and precursors of an amorphous semiconductor matrix material and then depositing said mixture on the substrate.

4) The method of claim 2, wherein the forming the amorphous semiconductor matrix is carried out by deposition of precursor material followed by conversion of the precursor material to the amorphous semiconductor material.

5) The method of claim 2, wherein the forming of the amorphous semiconductor matrix is carried out by deposition of the amorphous semiconductor material.

6) The method of claim 1, wherein the semiconductor nanocrystals are from 2-30 nm in size.

7) The method of claim 1, wherein the semiconductor nanocrystals are selected from the group consisting of lead selenide, lead sulfide and germanium.

8) The method of claim 1, wherein the amorphous semiconductor matrix comprises material selected from the group consisting of silicon, germanium, and a silicon-germanium alloy (Si₁₋ₓGeₓ).

9) The method of claim 1, wherein the subjecting the materials from a) to crystallizing conditions is carried out by laser annealing.

10) The method of claim 1, wherein the semiconductor nanocrystals are present in the matrix at a volume fraction of from 0.2 to 0.74.

11) The method of claim 1, wherein the thickness of the nanocrystal composite material is from 20 to 400 nm.

12) A nanocrystal composite material comprising a plurality of semiconductor nanocrystals incorporated into a crystalline semiconductor matrix, wherein the majority of the nanocrystals have an ordered arrangement within the composite.

13) The composition of claim 12, wherein the semiconductor nanocrystals are selected from the group consisting of lead selenide, lead sulfide and germanium.

14) The composition of claim 12, wherein the semiconductor nanocrystals are from 2-30 nm in size.

15) The composition of claim 12, wherein the amorphous semiconductor matrix comprises material selected from the group consisting of silicon, germanium, and a silicon-germanium alloy (Si₁₋ₓGeₓ).

16) The composition of claim 12, wherein the thickness of the nanocrystal composite material is from 20 nm to 400 nm.

17) The composition of claim 14, wherein the crystalline semiconductor matrix is comprises silicon and the silicon grains are from 8 to 20 nm.

18) The composition of claim 12, wherein each of at least a majority of nanocrystals are electrically connected to adjacent nanocrystals.

19) A device for converting photons and/or thermal energy to electrical energy comprising:
at least two spaced electrodes; and
at least one layer comprising the nanocrystal composite material of claim 12 disposed between the two spaced electrodes.

20) The device of claim 19, wherein the nanocrystal composite material comprises lead selenide nanocrystals and silicon matrix.
